(19) United States
(12) Patent Application Publication
(10) Pub. No.: US 2006/0118729 A1
(43) Pub. Date: Jun. 8, 2006

(54) Multicycle integration focal plane array (MIFPA) for lock-in (LI-), gated (G-), and gated lock-in (GLI-) imaging, spectroscopy and spectroscopic imaging

(76) Inventors: Ken K. Chin, Pine Brook, NJ (US); Haijiang Ou, Endicott, NY (US)

Correspondence Address: Ken K. Chin, 3 Le Mans Place, Pine Brook, NJ, 07058, US

(21) Appl. No.: 11/002,861

(22) Filed: Dec. 2, 2004

(51) Int. Cl. H01L 27/14

(52) U.S. Cl. 250/370.08

(57) ABSTRACT

A new electronic apparatus multicycle integration focal plane array (MIFPA) is disclosed, wherein by using correlated multicycle integrators (CMI, U.S. Pat. No. 6,630,669) extremely weak signals buried in strong background can be detected for imaging, spectroscopy, and/or spectroscopic imaging applications. The MIFPA apparatus can operate in three modes—the lock-in (LI), gated (G), and gated lock-in (GLI) modes. The methods of operating LI-MIFPA, G-MIFPA, and GLI-MIFPAP modes comprising specific steps are also disclosed.

### BACKGROUND OF THE INVENTION

1. Field of the Invention

This invention relates to the theory, design, fabrication, performance, and methods of its applications of a new electronic device—a new type of staring focal plane array (FPA), which utilizes the method of multicycle integration (MI) with the correlated multicycle integrators (CMI, U.S. Pat. No. 6,630,669) to acquire the signal. The new device is called multicycle integration focal plane array (MIFPA). MIFPA makes lock-in amplification and boxcar-gated integration, which work so far only for a single detector, feasible for array configuration. MIFPA has three modes of operation—lock-in (LI), gated (G), and gated lock-in (GLI) modes. The application of MIFPA is in the detection of extremely weak imaging, spectroscopic, and spectroscopic imaging.

2. Description of Prior Art

In the past few decades, the lock-in amplifier and boxcar-gated integrator have played important roles in the detection of extremely weak signals buried in strong background noises. However, the lock-in amplifier and boxcar-gated integrator, being sophisticated electronics systems, work only for a single detector. For array detectors, either linear or area, for imaging, spectroscopic, and spectroscopic imaging applications, the staring focal plane arrays (FPA) were invented. In the existing FPA technology, each pixel has a semiconductor photodiode, the photocurrent (signal plus background) of which goes through single-cycle integration (SI). When signal is extremely weak in comparison with background, the signal to noise ratio, dynamic range, and other criteria of performance of the existing single-cycle integration focal plane array (SIFPA) are limited by its integration time. It cannot achieve the level of performance of the lock-in amplifier. By replacing the FPA's single-cycle integration (SI) with multi-cycle integration (MI), we turn SIFPA into MIFPA. MIFPA can operate in three modes—lock-in (LI), gated (G), and gated lock-in (GLI) modes. LI-MIFPA and G-MIFPA incorporate the concepts of lock-in amplifier and gated integrator into the array configuration, respectively. LI-MIFPA can perform lock-in imaging, spectroscopy, and or spectroscopic imaging. G-MIFPA can perform gated imaging, spectroscopy, and or spectroscopic imaging. GLI-MIFPA has the features of both LI-MIFPA and G-MIFPA.

### SUMMARY OF THE INVENTION

A new type of focal plane array (FPA)—multi-cycle integration focal plane array (MIFPA) that utilizes the patented device correlated multicycle integrator (CMI)—has been invented for lock-in, gated, or gated lock-in detection of extremely weak image and/or spectroscopic signals buried in strong background. The principles, theory, circuit designs, computer simulation, fabrication, experimental results, and application methods of the MIFPA are disclosed. The total signal integration time of the MIFPA is several orders greater than the single-cycle integration focal plane array (SIFPA), which is the existing FPA technology. As a result, the sensitivity of weak signal detection, the dynamic range, and other criteria of performance of the MIFPA are several orders better than those of the SIFPA. In addition, the MIFPA also reduces significantly low-frequency noises. This essential feature of MIFPA is the reason why MIFPA is far better than the widely used method of multi-image (acquired by the existing SIFPA technology) averaging using image processing software, which inevitably includes the low frequency noise and other noises associated with the multiple utilization of the A/D converter of the data acquisition system. The MIFPA can operate in three modes—the lock-in (LI), gated (G), and gated lock-in (GLI) modes.

In LI-MIFPA, radiation from the scene or object, and therefore the signal photocurrent, is modulated either passively or actively, while dark and/or background currents are not. By using a correlated multi-cycle integrator, the signal current is accumulated while the dark or background current is cancelled. As a result, the total integration time for each pixel is increased by several orders, and so is the improvement of the imager's signal to noise ratio and dynamic range. In G-MIFPA, the direction of integration of the correlated multi-cycle integrator does not change as in the BC-MIPFA. The integrator is triggered on by the arrival of the pulse of signal photocurrent, and turned off after the pulse disappears. It remains inactive until its trigger by the arrival of the next pulse of signal photocurrent. The LI-mode is used for the detection of extremely weak constant signal. The G-mode is appropriate for periodically arrived (for example, a pulsed-laser excited fluorescence spectroscopy) short photocurrent pulses. The GLI-mode is for periodical pulsed signal, which is buried under strong background, and therefore the principles of both LI-mode and G-mode are utilized.

MIFPA is a generic electronic device that can be used for imaging, spectroscopy, and/or spectroscopic imaging. It is valid for any source of signal electrical current, including photonic, electrical, magnetic, and thermal. The principles and circuit designs of MIFPA can be used as long as the signal is extremely weak and/or short in comparison to the background. It is not limited by the specific method of lock-in and/or gating, neither is it by the type of detectors.

### BRIEF DESCRIPTION OF THE SYMBOLS AND DRAWINGS

1. Definition of Symbols

Iₛ DC image signal photocurrent generated in the detector by the scene of imaging. Iₛ is defined as the average of the real image signal current iₛ, which is time varying, through its integration cycle.
I_{d} DC dark current thermally generated. I_{d} is defined as the average of the time-varying real dark current i_{d}.
I_{b} DC background current, which is generated by photons of the same wavelengths under detection. As Iₛ and I_{d}, I_{b} is defined as the average of the time varying real background current i_{b}. When I_{b} can be modulated separately from signal current Iₛ, the background current I_{b} plays the same role as the dark current I_{d}. In this invention, we treat I_{b} and I_{d} as equivalent, using I_{b} to denote both of them.
e charge of an electron, 1.6×10⁻¹⁹ C.
Nₛ number of integrated photoelectrons generated by a steady signal photon flux.
\overline{nᵣₒ²} noise due to readout electronics.
\overline{n_{1/f}²} or low frequency noise mostly associated with the fabrication process of the photodetector.
\overline{ₜₕ²} detector thermal noise.
\overline{nₛ²} shot noises associated with the steady signal current.
\overline{n_{b}²} shot noises associated with the steady background current.
{square root over (\overline{n_{b}²})} root mean square (rms) value of background current generated shot noise, which is the predominant noise source under the condition of Iₛ<<I_{b}.
Nₛₐₜ saturation or maximum number of electrons that an integration capacitor can handle.
m number of integration cycles of the correlated multi-cycle integrator.
τ period of each cycle of integration for lock-in MIFPA.
τₒₙ gate-on or integration duration time for gated or gated lock-in MIFPA.
τ_{off} gate-off or non-integration duration time for gated or gated lock-in MIFPA.
α weigh of gate-on duration, defined as

$$α = \frac{{τ}_{on}}{τ} = \frac{{τ}_{on}}{{τ}_{on} + {τ}_{off}}$$
Tᵢ Total integration time.
   for LI-MIFPA, Tᵢ=mτ;
   for G-MIFPA and GLI-MIFPA, Tᵢ=mατ=mτₒₙ.
R Signal to noise ratio, defined as

$$R = Signal / Noise = \frac{{N}_{s}}{\sqrt{ \overline{{n}^{2}}}} ,$$

where Nₛ is the number of electrons due to the signal current Iₛ, and \overline{n²} is the root mean square value of the total number of electrons due to random noise.
D Dynamic range in decibels, defined as D=20 log₁₀Rₘₐₓ, when the maximum integration time is utilized.
f Frequency.
m number of integration cycles of MIFPA
ω Angular frequency. ω=2πf
ωₘ Modulation frequency. ωₘ=2π fₘ=2π/τ.
T(ω) Noise transmission window of a conventional single cycle integrator for a conventional FPA T(ω)=\sqrt{Vₒ(ω, φ)Vₒ^{•}(ω,φ)}, where Vₒ(ω,φ) is the output voltage of the integrator with a unit harmonic current i(t)=e^{j(ωt+φ)} as the input.
Tₘ(ω) Noise transmission window of a correlated multi-cycle integrator for a LI-MIFPA
T_{P-L}(ω) Transmission window of typical phase sensitive detector plus low pass filter
T_{LI}(ω) Transmission window of typical single detector lock-in amplifier
H_{L}(ω) Transfer function of low pass filter
H_{S}(ω) Transfer function of signal channel
   2. List of Figures

FIG. 1 is The Principles of Lock-In Multicycle Integration Focal Plane Array (LI-MIFPA)

FIG. 2 is Block Diagram of Lock-in Multicycle Integration Focal Plane Array (LI-MIFPA)

FIG. 3 is Relative Noise Power Spectra of Integrators
Solid Curve: Tₘ²(ω) of a correlated multi cycle integrator used in MIFPA
Dashed Curve: T²(ω) of a single cycle integrator used in conventional SIFPA

FIG. 4 is Transmission Windows of MIFPA, PSD+LPF, and Lock-in Amplifier

FIG. 5 is Principles of Gated Multicycle Integration Focal Plane Array (G-MIFPA) and Gated Lock-in Multicycle Integration Focal Plane Array (GLI-MIFPA)
(a) Gated Multicycle Integration
(b) Gated Lock-in Multicycle Integration

FIG. 6 is Schematic of Circuit Design of the Correlated Multi-Cycle Integrator (CMI) of MIFPA

FIG. 7 is Computer Simulation Results of the Correlated Multi-Cycle Integrator (CMI) of MIFPA

FIG. 8 is The Layout of VLSI Design of the Silicon Chip with CMI and MIFPA Circuitries

FIG. 9 is Experimental Results of the Correlated Multi-Cycle Integrator (CMI) of MIFPA

FIG. 10 is Experimental Results of the Sensitivity of the Correlated Multi-Cycle Integrator (CMI) of MIFPA

FIG. 11 is (a) Imaging of Lock-in MIFPA Using a Single CMI
(b) Conventional Imaging of SIFPA

FIG. 12 is Block Diagram of MIFPA with Shared CMI and Sample/Hold

FIG. 13 is Circuitry and Control Timing of MIFPA with Shared CMI and Sample/Hold

FIG. 14 is Block Diagram of MIFPA with Non-Shared CMI and Shared Sample/Hold

FIG. 15 is Circuitry and Control Timing of MIFPA with Non-Shared CMI and Shared Sample/Hold

FIG. 16 is (a) Imaging of Lock-in MIFPA Using a 1×4 CMI Array
(b) Conventional Imaging of SIFPA

### DETAILED DESCRIPTION OF THE INVENTION

During the course of this description, like numbers will be used to identify like elements according to different figures which illustrate the invention.

1. Deficiencies of Existing FPA Technology for Detecting Extremely Weak Signals

The lock-in (LI) amplifier and gated integrator (GI) have been playing important roles in the detection of weak photon signals. They were developed for a single photodetector. For the focal plane array (FPA) or image sensor, which utilizes a staring linear or area array of photodetectors to simultaneously detect an array of photon signals, the periodic integration of photocurrent is used to improve signal to noise ratio. The sensitivity of a semiconductor photodetector is characterized by its signal to noise (voltage or current) ratio R

$$R = Signal / Noise = \frac{{N}_{s}}{\sqrt{ \overline{{n}_{ro}^{2}} + \overline{{n}_{1 / f}^{2}} + \overline{{n}_{th}^{2}} + \overline{{n}_{s}^{2}} + \overline{{n}_{b}^{2}}}} \qquad ( 1 )$$

where Nₛ is the number of integrated photoelectrons generated by a steady signal photon flux, and the denominator is the root mean square (rms) value of the total number of noise electrons. The noise electrons are from various sources. \overline{nᵣₒ²} is the noise due to readout electronics, \overline{n_{1/f}²} the 1/f or low frequency noise mostly associated with the fabrication process of the photodetector, n h the detector thermal noise, and \overline{nₛ²} and \overline{n_{b}²} the shot noises associated with the steady signal and background currents, respectively. Note that the DC background current I_{b} and dark current I_{d} have the same effect. We use I_{b} to represent the sum of I_{b} and I_{d}, and \overline{n_{b}²} to represent the rms value of the number of noise electrons associated with I_{b} and I_{d}. When I_{b} (DC) is several orders greater than signal current Iₛ (DC), the shot noise \overline{n_{b}²} may be predominant among all the components of the noise electrons. Therefore, Eq. (1) can be simplified as

$$R = Signal / Noise \approx \frac{{N}_{s}}{\sqrt{ \overline{{n}_{b}^{2}}}} = \frac{{N}_{s}}{\sqrt{ {N}_{b}}} = \frac{{I}_{s}}{\sqrt{e {I}_{b}}} \sqrt{{T}_{i}} \qquad ( 2 )$$

where N_{b} is the number of integrated electrons due to DC background and/or dark current I_{d}, e the electron charge, Tᵢ the signal integration time (approximately equal to the frame period for a staring FPA). Here we use the equation

$$\overline{{n}_{b}^{2}} = {N}_{b} = \frac{{I}_{b} {T}_{i}}{e} \qquad ( 3 )$$

which is valid for photovoltaic detectors. If the detectors are photoconductors, such as QWIP's, the rms value \sqrt{n_{b}²} of background current generated shot noise electrons as expressed by Eq. (3) will be multiplied by a factor of square root of 2. Other equations in the following discussion will be modified with a similar factor of correction, which does not affect substantially our conclusions of MIFPA.

Eq. (2) indicates that the signal to noise ratio is proportional to the square root of integration time Tᵢ of each pixel. However, T is limited by Nₛₐₜ, the saturation or maximum number of electrons that an integration capacitor can handle. Note that Nₛₐₜ is limited by two factors. First, the capacitance can only be in the range of pF due to real estate limit in the FPA; secondly, the increase of the capacitance will induce a higher kTC noise. All the existing FPA technologies use single-cycle integration (SI) of signal (note that in the case of gated intensified CCD imaging system the FPA still operates in SI mode). For the CMOS FPA, the capacitance trans-impedance amplifier (CTIA) is the most widely used readout interface. Thus

$${T}_{i} = \frac{e {N}_{sat}}{{I}_{s} + {I}_{b}} \approx \frac{{eN}_{sat}}{{I}_{b}} \qquad ( 4 )$$

Using signal integration time defined by Eq. (3), we can obtain the optimized signal to noise ratio for the existing single-cycle integration focal plane array (SIFPA) technology using CTIA

$${R}_{SIFPA , opt} = {( Signal / Noise )}_{SIFPA , max} \approx \frac{{I}_{s}}{{I}_{b}} \sqrt{{N}_{sat}} \qquad ( 5 )$$

Assuming R_{SIFPA,oppt}=1, we have the theoretical minimum detectable signal current to background current ratio for a SIFPA

$${( {I}_{s} / {I}_{b} )}_{SIFPA , min} \approx \frac{1}{\sqrt{{N}_{sat}}} = 1.63 \times {10}^{- 4} \qquad ( 6 )$$

where we assume that the integrator has a storage capacitor with capacitance of 2 pF and saturation voltage of 3V. Apparently, the existing FPA technology of single-cycle integration (SI) is inadequate to deal with many cases, in which the signal photocurrent to background current ratio Iₛ/I_{b} is extremely low, such as visible and infrared (IR) solar magnetography (<10⁻⁴), liquid nitrogen temperature imaging using long wave length infrared (LWIR, 8-12 μ)) quantum well infrared photodetector (QWIP) array, 15 μ very long wavelength (VLWIR) imaging in space (1⁻⁶˜10⁻⁵), Raman spectroscopy with near infrared (NIR) excitation, and VLWIR spectroscopic imaging of biomedical specimens (<10⁻⁶).
2. Principles of Multicycle Integration Focal Plane Array (MIFPA)

For extremely weak signal detection, by replacing single-cycle integration (SI) with multicycle integration (MI), we can increase the integration time by several orders, and therefore dramatically improve the performance of the FPA, including (but not limited to) sensitivity and dynamic range. The multicycle integration focal plane array (MIFPA) can operate in lock-in (LI), gated (G), and gated lock-in (GLI) modes.

2.1. Lock-In Multi-cycle Integration Focal Plane Array (LI-MIFPA)

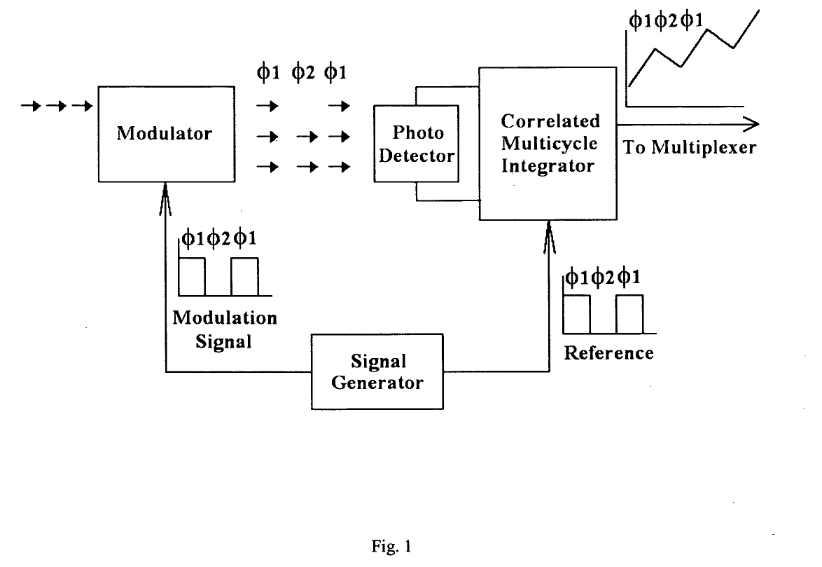

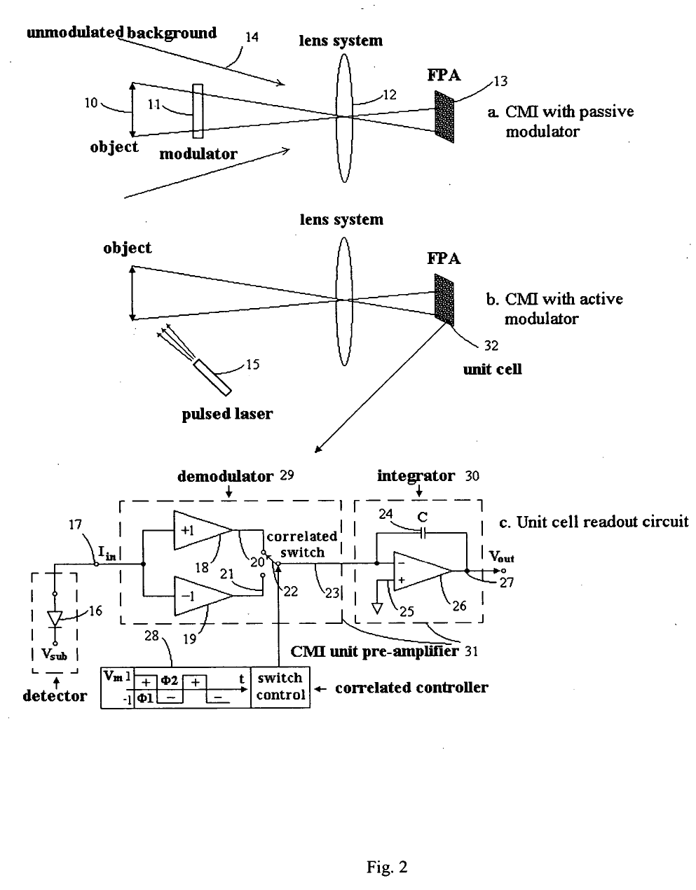

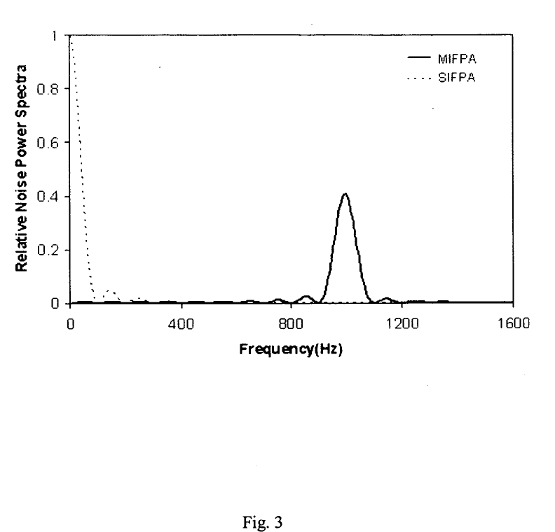

To elicit the principles of MIFPA, we use its basic operation mode—lock-in focal plane array (LI-MIFPA) for extremely weak signal imaging, the critical component of which is a correlated multicycle integrator (CMI, also called CMI unit-preamplifier) 31 for each pixel, as shown in FIGS. 1 and 2. LI-MIFPA's application for spectroscopy and spectroscopic imaging is an obvious extension of its application for imaging. The other two modes of operation—G-MIFPA and GLI-MIFPA—are similar to LI-MIFPA. The only difference is that the CMI of the G-MIFPA and GLI-MIFPA is programmed to shut off during the period of time when there is no signal, and the CMI of the LI-MIFPA keeps functioning.

The CMI accumulates the signal while canceling the background. The schematic shown in FIGS. 1 and 2(a) is for the simplest and most common case—imaging using passive modulation. A lens or lens system 12 is placed between the object or scene 10 and the focal plane array 13, composed of either one- or two-dimensional of photodetectors 16, where the image is formed. A passive optical modulator 11, which can be a mechanic chopper, an electric-optical switch, a polarizer, or other devices, is placed between the object 10 and the FPA 13 to modulate the photon flux from the scene or object for imaging, spectrum, or spectroscopic imaging. The signal can also be actively modulated by a pulsed light source 15 (FIG. 2 (b)), in which the signal photon flux is generated by modulated power source, such as a pulse laser. When the modulator is on in one phase (φ1 in the figure), the current generated by the detector will be the signal photocurrent Iₛ from object 10, plus the DC background current I_{b} from the radiation 14 not modulated. When the radiation from the imaging target is blocked by the modulator in another phase φ2 of equal duration as φ1, only the DC I_{b} is present. By controlling the correlated multicycle integrator synchronically with the modulation control signal, the integrator charges the capacitor with the signal and background currents in φ1, but discharges it with background current only in φ2. Discharged by the background current in each cycle, the capacitor is saved for signal current integration, and the total integration time is increased.

The photocurrent 17 or Iᵢₙ(Iᵢₙ=Iₛ+I_{b}) generated by each photodetector 16, which is composed of the modulated Iₛ from object 10 and the DC current I_{b} from the unmodulated radiation 14 or dark current, is fed to either 18 or 19 of the demodulator 29, controlled by the correlated controller 28. 28 is a square wave generator, which controls both the modulator 10 or 15 and the demodulator 29. The output of 29, which is Iₛ+I_{b} during phase φ1 and −I_{b} during phase φ2, is fed to an integrator 30, the most commonly used version of which is the capacitance transimpedance amplifier (CTIA). The demodulator and the integrator are the two critical components of the conventional lock-in amplifier. The demodulator and the integrator are combined in MIFPA and called correlated multicycle integrator (CMI) 31.

The advantages of LI-MIFPA over SIFPA are:

2.1.1. Advantages of Lock-In Multi-Cycle Integration Focal Plane Array (LI-MIFPA)

(a) Improvement of Signal to Noise Ratio

In LI-MIFPA, Eq. (4) is replaced by

$$T \approx \frac{{eN}_{sat}}{{I}_{s}} \qquad ( 7 )$$

Using signal integration time defined by (6), we can obtain the optimized signal to noise ratio for MIFPA

$${R}_{MIFPA , opt} = {( Signal / Noise )}_{MIFPA , max} \approx \sqrt{\frac{{I}_{s}}{2 {I}_{b}}} \sqrt{{N}_{sat}} \qquad ( 8 )$$

The improvement of signal to noise ratio is a factor of

$$\sqrt{\frac{{I}_{b}}{2 {I}_{s}}} \qquad ( 9 )$$

Assuming R_{MIFPA,opt}=1 in (7), for the same integration capacitance and saturation voltage, we have BC-MIFPA's theoretical minimum detectable signal to background ratio

$${( \frac{{I}_{s}}{{I}_{b}} )}_{MIFPA , min} \approx \frac{2}{{N}_{sat}} = 5.04 ⨯ {10}^{- 8} \qquad ( 10 )$$

A comparison of (10) and (6) shows that the BC-MIFPA improves the weakest detectable signal, as well as signal to noise ratio, by more than three orders.
(b) Improvement of Dynamic Range

In addition to signal to noise ratio and weakest detectable signal, another important figure of merit of a focal plane array is its dynamic range. In terms of decibels, the dynamic range D of a conventional SIFPA is

$${D}_{SIFPA} = 20 {log}_{10} {R}_{SIFPA , max} = 20 {log}_{10} ( \frac{{I}_{s}}{{I}_{b}} \sqrt{{N}_{sat}} ) \qquad ( 11 )$$

whereas for a MIFPA it is

$${D}_{MIFPA} = 20 {log}_{10} ( \sqrt{\frac{{I}_{s} {N}_{sat}}{{I}_{b}}} ) \qquad ( 12 )$$

The improvement of dynamic range is

$${D}_{MIFPA} - {D}_{SIFPA} = 20 {log}_{10} ( \sqrt{\frac{{I}_{b}}{{I}_{s}}} ) \qquad ( 13 )$$

If I_{b}/Iₛ>10⁴ as in the case of solar magnetography, improvement of dynamic range will be more than 37 dB.

(c) Suppression of Low Frequency Noise

As shown in FIG. 1, in the method of BC-MIFPA both the signal and background are fed to the correlated multicycle integrator. The noise current generated in the detector also goes through the correlated multicycle integrator. The noise transmission window of the correlated multicycle integrator is

$${T}_{m} ( ω ) = \sqrt{{V}_{o} ( ω , ϕ ) {V}_{o}^{*} ( ω , ϕ )} = \frac{T}{C} \vert \frac{tan ( \frac{ω T}{4 m} ) sin ( \frac{ω T}{2} )}{\frac{ω T}{2}} \vert \qquad ( 14 )$$

where T is the total integration time, m the modulation frequency, and C the charge storage capacitor. For comparison, also shown in FIG. 2 is the noise transmission window (15) of a single-cycle integrator used in a conventional SIFPA

$$T ( ω ) = \sqrt{{V}_{o} ( ω , ϕ ) {V}_{o}^{*} ( ω , ϕ )} = \frac{\vert 2 sin ( \frac{ω T}{2} ) \vert}{ω C} \qquad ( 15 )$$

In both cases, the rms value of the total number of noise electrons is the same

$$\sqrt{\overline{{n}_{b}^{2}}} = \sqrt{\overline{{V}_{n}^{2}}} \frac{C}{ⅇ} = {\frac{C}{ⅇ} [ {\int }_{0}^{∞} {T}^{2} ( ω ) w ( f ) ⅆ f ]}^{1 / 2} = \sqrt{{I}_{b} T / ⅇ} = \sqrt{{N}_{b}} \qquad ( 16 )$$

for the same total integration time. Comparing the two spectra of FIG. 2, however, we note that the transmission function T(ω) of a single-cycle integrator is that of a low pass filter with bandwidth equal to ½T, while the transmission function of the correlated multicycle integrator is that of a band pass filter peaked at the modulation frequency ωₘ, with satellite windows centered at the odd harmonics of ωₘ. An apparent advantage of LI-MIFPA then lies in its capability of suppressing the flicker or 1/ff noise, which, among all the noise sources, is usually important, and even dominant for some types of widely used detectors, such as InGaAs, InSb, and HgCdTe IR photodetectors.
(d) On-Chip Data Processing

In current FPA technology, multi-image (up to 10,000 images in solar magnetography) averaging with image processing software is utilized to extract extremely weak signal buried in strong background. Even with the help of dithering, this averaging method is limited and unreliable. In contrast, BC-MIFPA performs various functions of on-chip data processing, including addition, subtraction, averaging, and direct extraction of useful signals. As a recent trend in the development of FPA, direct on-chip data processing is preferred because of its efficiency. We can effectively avoid the system limitations imposed by the slow speed and statistical errors imposed by the high precision analog to digital converter. In addition, SIFPA's multi-image averaging will inevitably include the 1/f noise, which is eliminated by MIFPA.

2.1.2. Comparison of Lock-in MIFPA and Conventional Lock-In Amplifier

The block diagram of a basic lock-in amplifier is shown in FIG. 3. The key components are the phase sensitive detector (PSD), which demodulates the modulated signal to recover the signal as DC or low frequency components, and the low pass filter (LPF), which reduces the bandwidth of the noise (the signal as well), recovering weak signals buried in strong noise. In frequent domain \overline{ω}, a unit harmonic input fed to the PSD leads to an output from the LPF

$${V}_{out} ( ϖ ; ω , ϕ ) = \frac{2}{π j} {ⅇ}^{j ϕ} {\sum }_{k = - ∞}^{∞} \frac{1}{2 k + 1} δ [ ϖ - ( 2 k + 1 ) {ω}_{m} - ω ] {H}_{L} ( ϖ ) \qquad ( 17 )$$

where ω and φ are the frequency and phase of the input, respectively, and H_{L} is the transfer function of the LPF. Note that the output Vₒᵤₜ, which depends on the input ω and φ, is expressed in the frequency domain \overline{ω}. Since the LPF of most lock-in amplifiers has a very narrow bandwidth, the output only has DC and low frequency terms. Neglecting cross talk terms H_{L}[ω+(2 k+1)ωₘ]×H_{L}[ω+(2 k′+1)ωₘ], and following (14), we can calculate the transmission window of the PSD+LPF as a function of the input frequency

$${T}_{P - L} ( ω ) = {\sum }_{k = 0}^{∞} \frac{2}{( 2 k + 1 ) π} \vert {H}_{L} [ ω - ( 2 k + 1 ) {ω}_{m} ] \vert \qquad ( 18 )$$

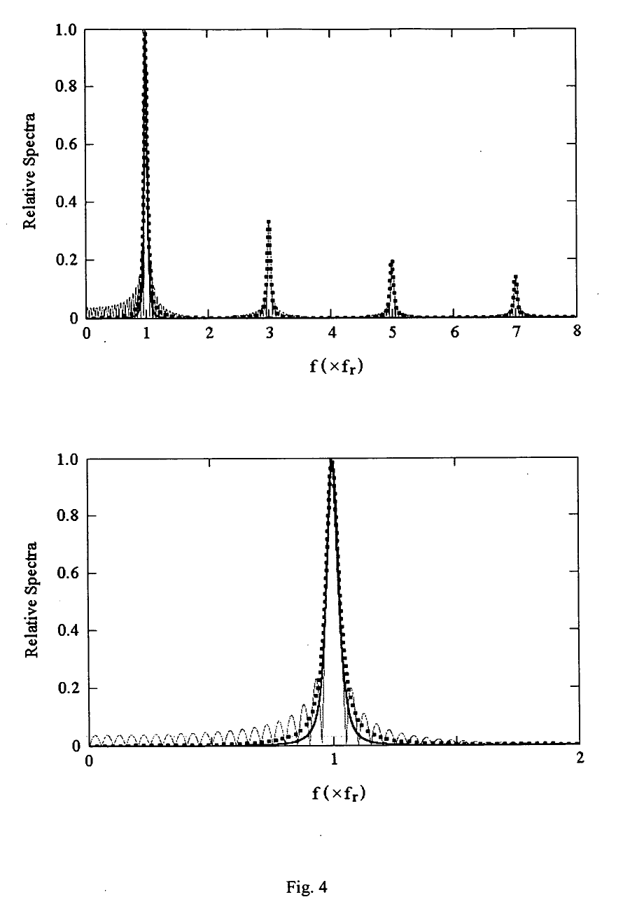

In addition to PSD+LPF, the typical lock-in amplifier has a pre-amplifier and a band pass filter in its signal channel. The pre-amplifier brings the small signal to a level sufficient to overcome the noise induced by the PSD, which is a switch that generates noises at various frequencies. The band-pass filter rejects unnecessary interference and noise by filtering out the satellite peaks of (19). Therefore the transmission window of the lock-in amplifier is a single peak centered at the modulation frequency, with its bandwidth defined by the LPF

$${T}_{LI} ( ω ) = \frac{2}{π} \vert {H}_{L} ( ω - {ω}_{m} \vert ⨯ \vert {H}_{s} ( ω ) \vert \qquad ( 19 )$$

where H_{S}(ω) is the transfer function of the signal channel. For comparison, (18), (19), and (14) are plotted in FIG. 4. Note that in FIG. 2, we plot (14) from 0 to the range of ωₘ, while in FIG. 4, we plot (14) for the whole wide range of spectrum, revealing its double satellite structure.

The critical component of LI-MIFPA is correlated multicycle integrator, which is a combination of phase sensitive detector and integrator. Since the integrator is a special type of low pass filter, LI-MIFPA is a special version of PSD+LPF. As shown in FIG. 4, (18) of the PSD+LPF of a typical lock in amplifier, which uses a second order RC low pass filter, and (14) of the LI-MIFPA have the similar feature of satellite peaks. The difference of (18) and (14) is in the sub-satellite peaks of the LI-MIFPA. Unlike the second order RC low pass filter, the transfer function of the integrator in LI-MIFPA has satellite peaks.

2.2. Gated Multicycle Integration Focal Plane Array (G-MIFPA)

MIFPA can also operate in gated (G) mode when signals appear in short pulses. In each cycle of integration with period r the on-time of the integrator is much shorter than the off-time (α<<1, FIG. 5). The G-MIFPA can operate without (FIG. 5.a) or with (FIG. 5.b) background cancellation. The device operates as the gated lock-in multicycle focal plane array (GLI-MIFPA) when it is programmed to perform background subtraction.

2.2.1. Simple Gated Multicycle Integration Focal Plane Array (G-MIFPA)

G-MIFPA is used when the number of integrated signal electrons is many orders smaller than that of the background and/or dark current electrons (αIₛ<<I_{b}, but αIₛ is not <<I_{b}, as in the case of IR fluorescence spectroscopy using nano-second pulse laser excitation), In G-MIFPA the direction of integration of the correlated multicycle integrator does not change as in the LI-MIPFA. The integrator is turned on by a trigger signal from the gate control circuit to integrate the signal photocurrent pulse, and turned off after a certain increment of time. It remains inactive until it is triggered again for the next signal pulse (FIG. 5.a). By keeping the integrator off we can avoid the shot noise when there is no signal.

2.2.2. Gated Lock-in Multicycle Integration Focal Plane Array (GLI-MIFPA)

If the signal is not only short, but is also associated with a much stronger background (in comparison with the background during the signal-off time, as in the case of LWIR spectroscopy using nano-second pulse laser excitation),
α<<1 (20)
Iₛ<<I_{b} (21)
then GLI-MIFPA can be used. In GLI-MIFPA, the correlated multicycle integrator of the GLIMIFPA goes through three phases (FIG. 5.b). In φ1, which lasts ατ, the integrator integrates both the signal pulse and strong background currents. In φ2, which has the same duration as φ1, the integrator reverses its direction of integration, and cancels the background of φ1. In φ3, which lasts much longer than φ1 or φ2, the integrator is turned off. The GLI-MIFPA combines the advantage of the G-mode—reduction of the on-time of the integrator to increase the integration time—and that of the LI mode—cancellation of background to increase the integration time.
3. Feasibility and Demonstraion of MIFPA
3.1. CMI Circuit Design

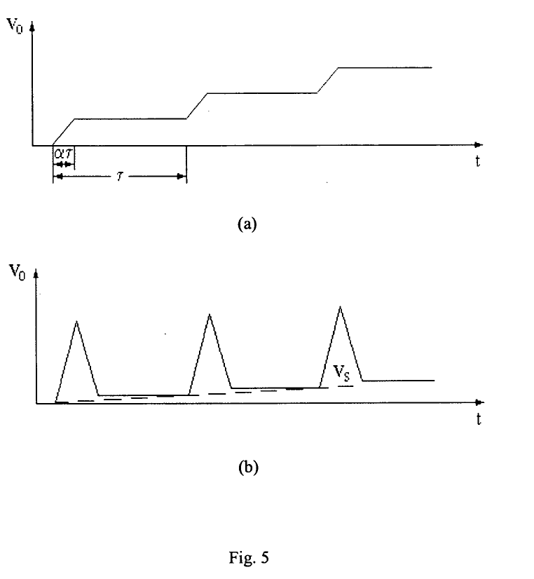

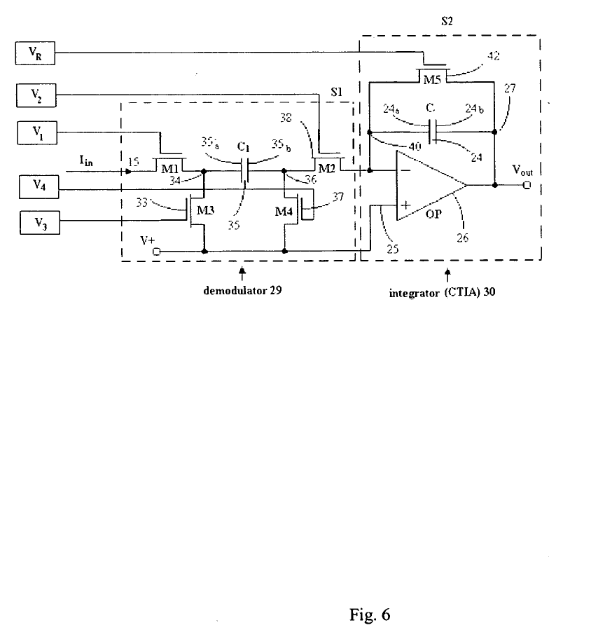

The fundamentaol difference of the conventional SIFPA and MIFPA is their integrator. The success of lock-in imaging using MIFPA depends on the circuit design of its correlated m ulticycle integrator (CMI), which must have as few devices as possible so that it can be incorporated into the array format. FIG. 6 is the patented (U.S. Pat. No. 6,630,669) CMI circuitry designed for MIFPA, which comprises two stages. The second stage S2 is integrator 30 (the same numbering as in FIGS. 1 and 2), the capacitive transimpedance amplifier (CTIA) widely used in the readout circuit of infrared (IR) FPA's. In this stage, 24 (the same as in FIG. 1) or feedback capacitor C of operational amplifier 26 (the same as in FIG. 1) is the main integrator, which accumulates signal throughout multi-cycle integration. 42 is the reset switch M5 enabled at beginning of integration with a narrow pulse, and reset after readout of the integrated signal. The first stage S1 is a special demodulator 29 (the same numbering as in FIGS. 1 and 2). In this stage, 35 or capacitor C₁ is a temporal integrator. M1, M2, M3, and M4 are the four MOSFET switches or gates of integrator 35. M1 is kept on during the cycle of integration and needed for any FPA integrator. Only M2, M3, and M4 play the function of correlated switches of the demodulator 29. The function of 29 is to integrate 17 (the same numbering as FIG. 1), or the input current Iᵢₙ(Iₛ+I_{d}) and to transfer the accumulated charges across 35a and 35b to 24a and 24b of C with opposite polarities depending on the gate timings. When M2 and M3 are off and M4 is on during φ2 (FIGS. 1 and 2), 17 or the input current Iᵢₙ is integrated on C₁ first. At the end of this half period of integration, by turning off M4 followed by turning on M2 and M3, the charges stored on 35b, the right plate of C₁, is transferred to 24a, the left plate of C. At the same time, C₁ is reset. Assuming that the charges stored on 35b are Q₁, the change of output voltage Vₒᵤₜ at node 27 or 24b after the transfer is ΔVₒₗ=−Q₁/C. At the next phase or half period of integration, with M3 and M4 off and M2 on (φ1 in FIG. 1), input current Iᵢₙ (15) charges C₁ and C. Assuming at the end of this period of integration the charges accumulated on 35b or the right plate of C₁ is Q₂, the change of output voltage Vₒᵤₜ at node 27 after the transfer is ΔV₂=Q₂/C. By modulating the signal current Iₛ and not modulating the background and/or dark current I_{d}, we have Q₁=Q_{d} and Q₂=Q_{d}+Qₛ, where Qₛ is the integrated charge due to signal current Iₛ, and Q_{d} the integrated charge due to background and/or dark current I_{b}. Therefore, the total change of output voltage Vₒ at node 41b or 27 after the two consecutive integrations is ΔVₒ=Qₛ/C. Note that for some type of signal modulation ΔVₒ=2 Qₛ/C. The function of the CMI method—integration of signal and cancellation of background—is thus fulfilled. The time sequence of the gate control voltages V_{1,} V_{2,} V_{3,} V_{4,} and V_{R} control the switches M1, M2, M3, M4, and M5, respectively, as described above. The substrate of the five FET switches M1, M2, M3, M4, and M5 are all grounded, which is not shown in FIG. 6.

3.2. CMI Circuit Simulation

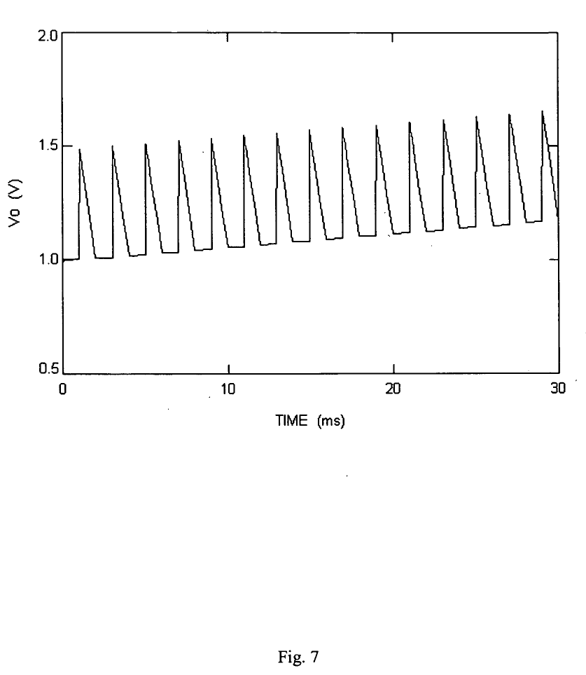

FIG. 7 is a computer simulation result of the Correlated Multicycle Integrator as shown in FIG. 6, by using the circuit simulation package HSPICE. 25 cycles of integration, with a total integration time of 5 ms, are shown in the figure. With the level of background current as shown in FIG. 7, the maximum integration time will be less than 0.5 ms if a single cycle integrator is used.

3.3. CMI Circuit Fabrication

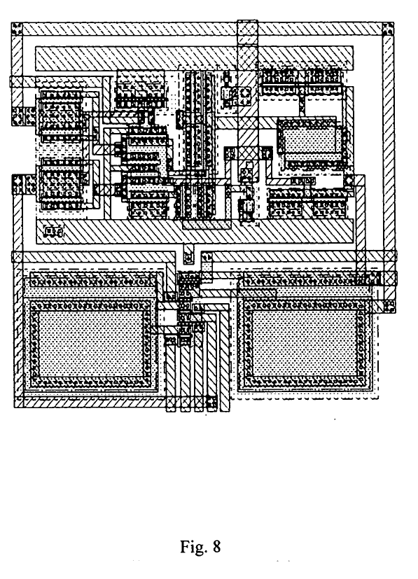

FIG. 8 is part of the layout of VLSI design of the silicon CMOS IC, which has various CMI circuitries, including CMI single pixels, and linear and area arrays of CMI with multiplexers, as well as device parameter test fixtures. The chip was designed using HP's 0.5 μ CMOS design rules, and fabricated at HP's 0.5 μ CMOS facility, which was managed by MOSIS.

3.4. Experimental Results of CMI

Three categories of experimental testing were performed on the CMI:

3.4.1. Testing of Multicycle Integration of CMI

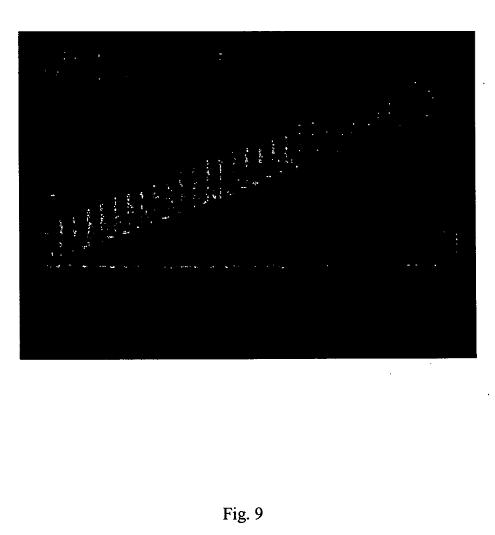

FIG. 9 is a photocopy of the graph taken from the screen of a tracer, which is used to test the design of the correlated multicycle integrator (CMI) as shown in FIG. 6. The Pulse Instrument Focal Plane Array Test Equipment setup is used to control the input and output of the Integrator. The modulation and correlated integration frequency of 31.25 kHz is generated by a pulse generator. With 30 cycles, a total time of 960 μs is used for integration. The data of test results were fed to a tracer. The output of the integrator has exactly the same features as the simulation results shown in FIG. 7. It is therefore demonstrated experimentally that the Correlated Multi-Cycle Integrator (CMI) functions as designed.

3.4.2. Testing of Sensitivity of CMI

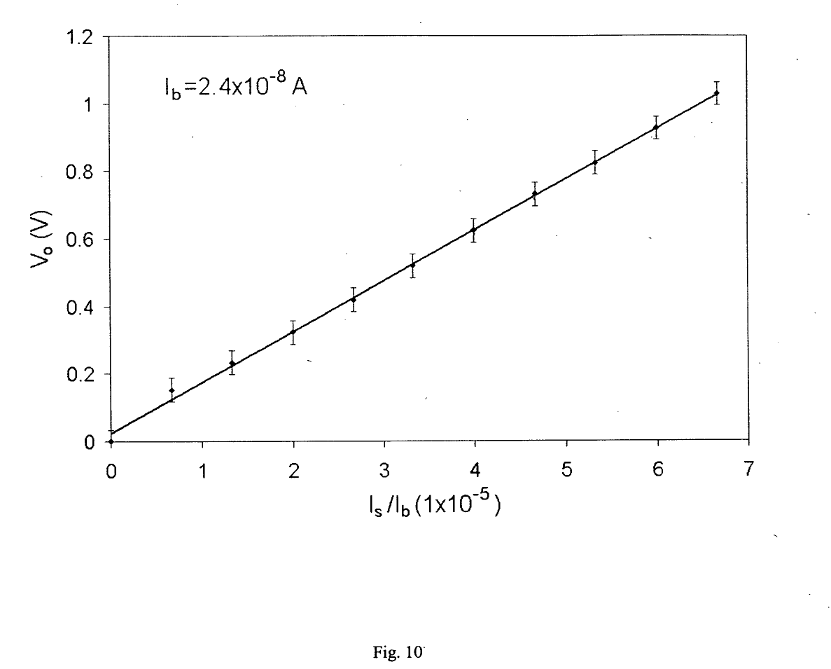

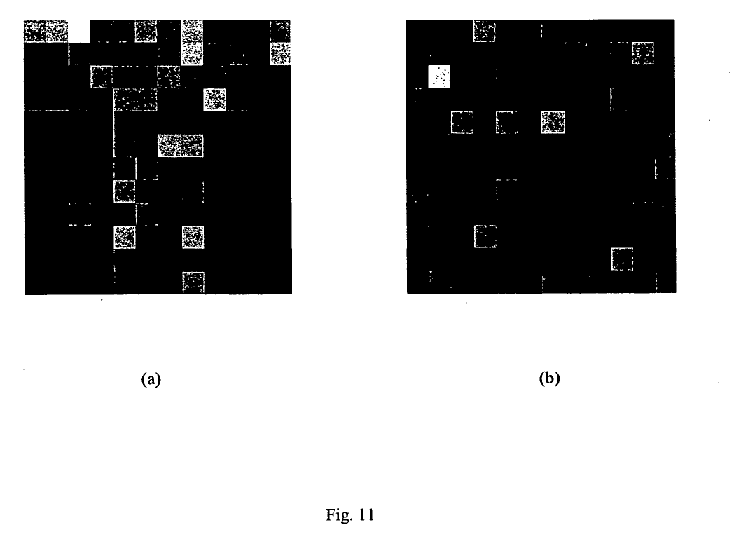

To test CMI's sensitivity, signal to noise ratio, and dynamic range, a near infrared (NR) light emitting diode (LED) powered by a DC source was used to generate the background photocurrent I_{b} 1.5×10⁻⁸ A, which was equivalent to a constant dark current I_{d} of the same magnitude in the NIR photodetector. A second NIR LED of the exact same characteristics, which was connected to a programmable square wave power supply with the same peak voltage as the DC power source of the first NIR LED. The second NIR LED generated modulated signal photocurrent Iₛ in the NIR photodetector. By adjusting the positions of the two LED's with respect to the photodetector, we can control the ratio of Iₛ/I_{b}. FIG. 10 shows the MIFPA output voltage Vₒ of the NIR photodiode as a function of the input Iₛ/I_{b}. The weakest signal measured in the experiment was (Iₛ/Iₛ)_{CMI,,Measured}=7×10⁻⁵. Note that the measured output error bar due to random fluctuation is 23 mV, the predominant source of which is the shot noise of the photodetector. By extending the straight line, or the output voltage Vₒ as a function of the input Iₛ/I_{b}, as shown in FIG. 10, we conclude that the weakest detectable signal Iₛ/I_{b} in our experiment is
(Iₛ/I_{b})_{min, CMI,,Experimental}˜1.4×10⁻⁵ (22)

A comparison of (22) and (6) shows that under the same background, the weakest measurable signal using our testing CMI-MIFPA chip is more than one order smaller than the theoretical limit of the measurable signal using the conventional FPA of single-cycle integration. Since other widely used figures of merit of the FPA, such as signal to noise ratio, dynamic range, and non-uniformity caused fixed pattern noise, are related to each pixel's weakest detectable signal, therefore we conclude that we have experimentally demonstrated the feasibility of CMI technology. Note that the theoretical limit of Eq. (9) was not achieved, since we used only 2,000 cycles of integration and a small portion of the available saturation output voltage of 3 V to avoid saturation. Saturation could b caused by feed through of capacitors, slow drifting of CMOS device parameters, and other instabilities of the electronics involved. With improvement of stability and uniformity of our devices and electronics, we can use longer integration time for of each cycle, as well as more cycles of integration. As a result, a longer total integration time that is close to the theoretical limit can be implemented. We expect that the theoretical limit of the weakest detectable signal as depicted by Equation (10) will be approached with the maturity of CMI-MIFPA technology.

3.4.3. Testing of Imaging Using a Single Pixel CMI

FIG. 11 (a) is the image of an object, which is taken by a single pixel or CMI of our first working CMI-MIFPA test chip, instead of the array, to avoid pixel nonuniformity induced noise. It is a letter T composed of 80 bright squares out of a total of 144 squares. While the dark squares do not generate any photocurrent, each of the bright squares generates a signal photocurrent of 1.05×10⁻¹² A in the photodetector, which is equal to 7×10⁻⁵ of the background photocurrent 1.5×10⁻⁸ A. FIG. 11 (b) is the “image,” or rather no image, of the same target under the same background (Iₛ=1.05×10⁻¹² A, unmodulated; and I_{b}=1.05×10⁻⁸ A) taken by the conventional imaging method of single-cycle integration. A comparison of FIG. 11 (a) and (b) clearly demonstrates the dramatic improvement MIFPA brings to the FPA technology of imaging and spectroscopy. Interestingly, we tried to “average” numerous figures (b) to obtain an image similar to (a). This widely used multi-image averaging method failed in our test.

3.5. MIFPA Structure, Circuit Design and Control Timing

To implement the CMI in array configuration for MIFPA performance, low frequency drifting noise during the long time of multicycle integration must be avoided. Two architectures of array with size of MXN are provided fro this purpose.

3.5.1. Shared CMI and Sample-Hold (One CMI and Sample/hold per Column)

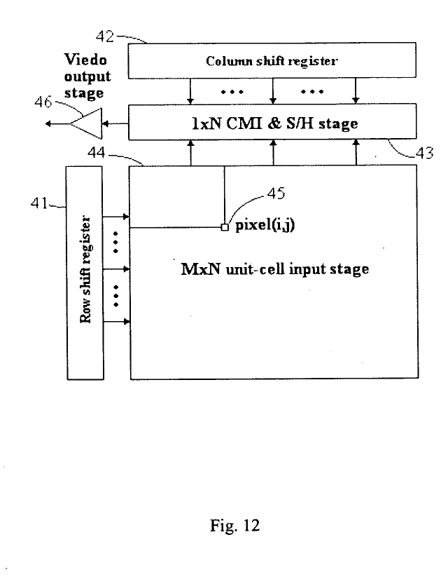

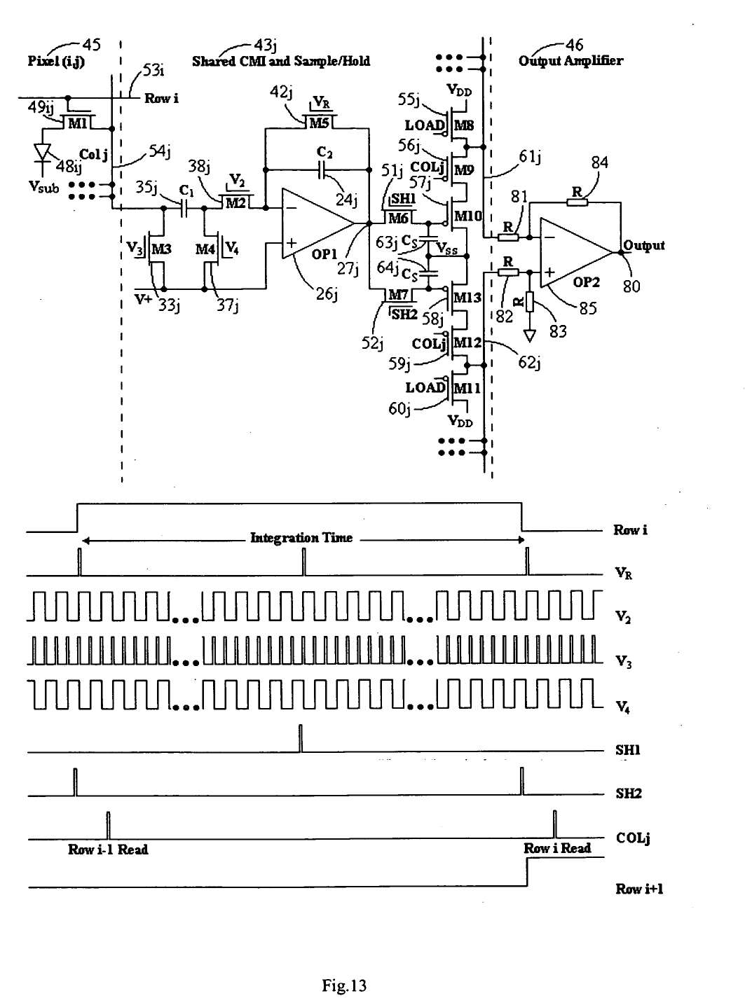

In this architecture, a stage of shared row of correlated multicycle integrators (CMI) as well as the sample/hold circuits performs the integration row by row. The block diagram of the structure is shown in FIG. 12. Its circuitry and timing is depicted in FIG. 13. The procedure is described as follow.

First the row shift-register 41 enables one row of detectors to be connected to the common shared CMI stage 43. Assume row i, depicted by 53i, is high, which turns on all the transistors 49ij (j=1, 2, . . . , N for all the cases discussed in this paragraph). Thus the detector 48ij will become the input of CMI 43j. After row i turns to high, a short pulse of V_{R} will reset the integrator capacitor 24j. By properly controlling the timing of V₂, V₃ V₄ as described in Section 3.1, the whole row of CMIs perform multicycle integration at either lock-in, gated, or gated lock-in mode. By the end of integration, the sample/hold switch 51j is turned on to sample the output voltage at node 27j to the hold capacitance of 63j. After the sample, V_{R} resets the capacitance 24j again. At the same time, the modulation signal is shifted a phase of 180 degrees to follow another similar integration. By the end of the second integration, the row shift register turns off the row i and is ready to turn on the next row i+1. Meanwhile, the sample/hold switch 52j is turned on to sample the output voltage at node 27j to the hold capacitance of 64j. At this time, 63j and 64j keep the integrated signals with phase difference of 180 degrees related to the detectors 48ij. After the second sample, the row shift-register enables the next row i+1. At the beginning of the next row integration, the column shift register starts to scan from column 1 to N to the jth column or COLj_to readout the signals of the previous row i. When COLj is enabled (logical low to turn on PMOS transistor), P transistors 57j and 59j activate the load transistors 55j and 60j, thus transistors 57j and 58j function as source follow, and the pair of voltages at 63j and 64j will be sensed to the inputs of the differential amplifier 46 at the nodes of 61j and 62j, respectively. These differential signals will eliminate the fixed pattern noises such as from the reset and feed-through of the switches. Thus, the differential signals of the whole row i will be readout serially at the output 80 before the first sample of the next row i+1 is taken. After the row shift register makes shift from 1 to M, the whole modulated image will be addressed.

It is ready to see that the integration time is much less than the frame period. The advantage of this approach is that in addition to the photodiode there is only one transistor per pixel. Thus, the pixel size is small, and the fill factor is high. The disadvantage is low efficiency.

3.5.2. Non-Shared CMI and Shared Sample/Hold (One CMI Per Pixel But One Sample/Hold Per Column)

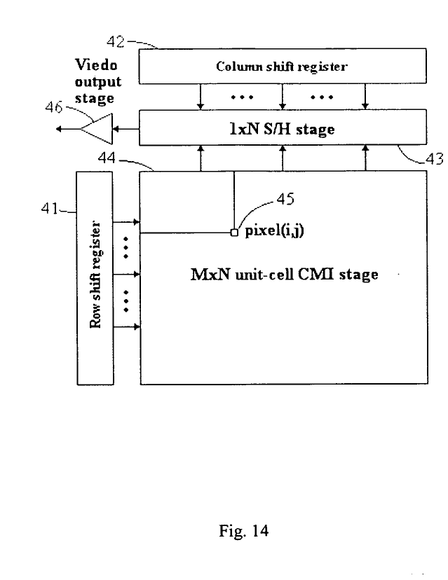

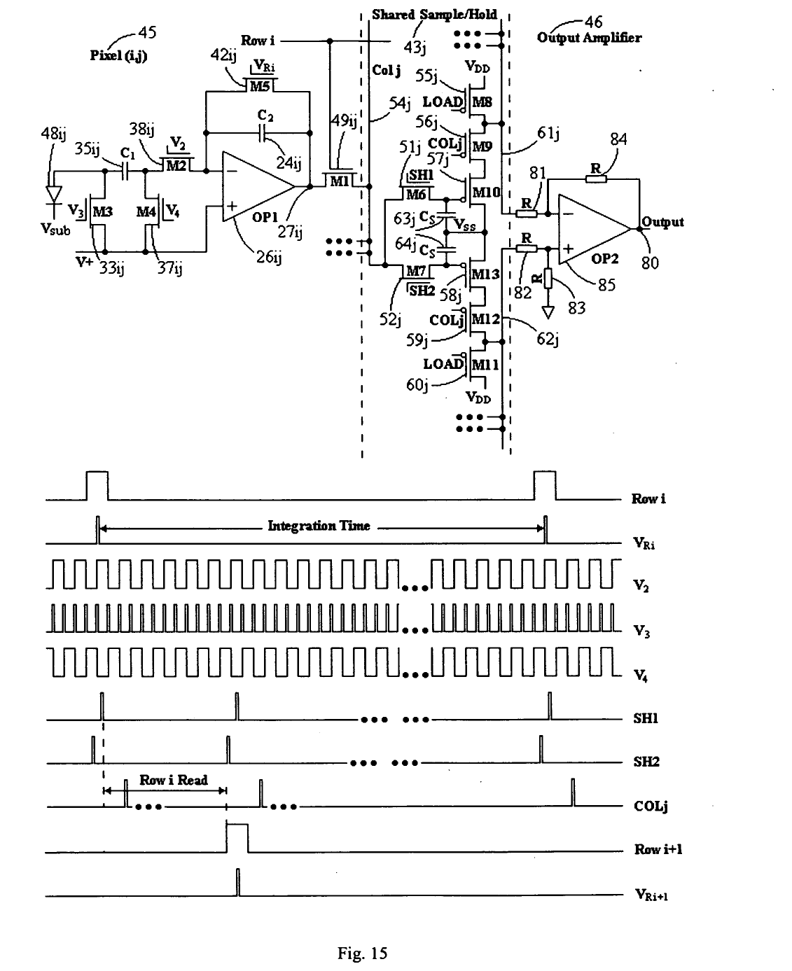

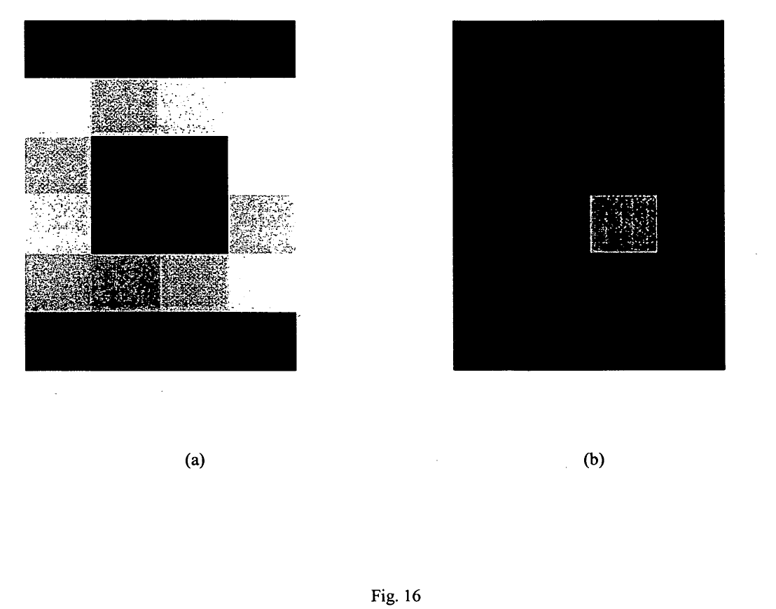

In the second architecture, every pixel's input unit includes a CMI preamplifier. A column sample and hold circuitry is shared to save the area. Signals are integrated also row by row. Every row has specified reset timing in the purpose to save readout time (done during integration). However, the integration of one row does not forbid the integration of other rows. The row shift register is used to select one row in a time for samples after integration and immediately after it is reset. Thus the differential of the two samples are used to get rid of the reset noise. The differential signals of the row then are readout serially by enabling or scanning the column shift register. The block diagram of the structure is shown in FIG. 14. Its circuitry and timing is depicted in FIG. 15. The procedure is described as follows.

The row shift-register 41 enables only one row in a time. The enabling of the row i makes the connection of the output 27ij (=1, 2, . . . , N for all the cases discussed in this paragraph) of the CMIij to the input 54j of the sample/hold circuitry. During the row enabling time, the sample/hold switch 51j is first turned on to sample the output voltage (end of the integration) at node 27ij to the hold capacitance of 63j, then the reset V_{Ri} is enabled to clean all the integration capacitances 24ij at the same row i. After the reset, the sample/hold switch 52j is then immediately turned on to sample the output voltage (at the beginning of the integration) at node 27j to the hold capacitance of 64j. After the second sample, the row shift register 41 turns off the row i, and the input units 45ij (i, with j=1, . . . N) start integration again. Before the next row is enabled, the signal stored in the shared sample/hold stage must be readout by enabling the column shift register 42. The column shift register starts to scan COLj to readout the signals of row i. When COLj is enabled (logical low to turn on PMOS transistor), P transistors 57j and 59j active the load transistors 55j and 60j, thus, the pair of voltages at 63j and 64j will be sensed to the inputs of the differential amplifier 46 at the nodes of 61j and 62j. The differential output voltages at node 80 are the integration signals from row i. After the readout of row i, the row shift register 41 turns on the next row i+1. Then, the procedure of sample and readout will be followed again until every pixel in the array is readout to make the image.

The advantage of this second approach is high efficiency, since the integration time is close to the frame time. The disadvantage is complexity of the circuitry, consuming more power, as well as low fill factor, since each pixel's input unit has a large area to contain the CMI.

3.6. MIFPA Circuit Fabrication

FIG. 8 is part of the layout of VLSI design of the silicon CMOS IC, which has various MIFPA circuitries, including single pixels, and linear and area arrays with multiplexers, as well as the circuitries presented in Section 3.5 and device parameter test fixtures. The chip was designed using HP's 0.5 μ CMOS design rules, and fabricated at HP's 0.5 μ CMOS facility, which was managed by MOSIS.

3.7. Experimental Results of MIFPA—Testing of Imaging Using a 1×4 CMI Array

FIG. 16 (a) is the image of an object, which is taken by a 1×4 CMI linear array and sample/hold (as presented in Section 3.5.1) of our first working CMI-MIFPA test chip. It is an object in the shape of □ composed of 12 bright squares out of a total of 16 squares. While the dark squares do not generate any measurable photocurrent, each of the bright squares generates a detectable signal photocurrent. FIG. 16 (b) is the “image,” or rather no image, of the same target under the same background taken by the conventional imaging method of single-cycle integration. A comparison of FIG. 16 (a) and (b) clearly demonstrates the dramatic improvement that MIFPA brings to the FPA technology of imaging and spectroscopy. Note that the MIFPA technology was demonstrated by using a single CMI in FIG. 11, and by using a 1×4 CMI linear array in FIG. 16.

What is claimed is:

1. Multicycle integration focal plane array (MIFPA), linear or area, which is a new type of electronic apparatus, and, unlike the existing FPA composed of a single-cycle integrator, is composed of
a) an array of correlated multicycle integrators, either one dimensional 43 or two dimensional 45, that can be incorporated into an integrated circuit for each pixel of the MIFPA to perform correlated multicycle integration;
b) and a linear array of sample/hold circuitries 43, to void noises;
c) wherein signal 10 being modulated either passively by a mechanical or electronic chopper 11 or actively by a pulsed light source 15 and background (and/or dark current) 14 being unmodulated;
d) wherein the input current 17 comprising the modulated signal and unmodulated background being fed to an integrator;
e) so that the signal being accumulated while the background being cancelled;
f) so that the signal to noise ratio and dynamic range can be greatly improved.

2. Multicycle integration focal plane array (MIFPA), linear or area, for the electromagnetic wave of microwave range (frequency from 10⁹ Hz up to 3×10¹¹ Hz, wavelength from 30 cm to 1.0 mm).

3. Multicycle integration focal plane array (MIFPA), linear or area, for the infrared range (frequency from 3×10¹¹ Hz to about 4×10¹⁴ Hz, wavelength from 1.0 mm to 780 nm).

4. Multicycle integration focal plane array (MIFPA), linear or area, for the visible range (frequency from 3.84×10¹⁴ Hz to about 7.69×10¹⁴ Hz, wavelength from 760 nm to 390 nm).

5. Multicycle integration focal plane array (MIFPA), linear or area, for the ultraviolet range (frequency from about 8×10¹⁴ Hz to about 3.4×10⁶ Hz, photon energy from roughly 3.2 eV to 100 eV).

6. Multicycle integration focal plane array (MIFPA), linear or area, for the X-ray range (frequency from roughly 2.4×10¹⁶ Hz to about 5×10¹⁹ Hz, photon energy from about 100 eV to 0.2 MeV).

7. The method of using MIFPA for the detection of extremely weak signals for imaging, spectroscopy, and spectroscopic imaging, which comprises the following steps:
a) a lens or lens system 12 is placed between the scene or object 10 for imaging, spectroscopy, or spectroscopic imaging and the multicycle integration focal plane array (MIFPA) 13, composed of either one- or two-dimensional of photodetectors 16, where the image and or spectroscopic signal is collected;
b) a passive optical modulator 11, which can be a mechanic chopper, an electric-optical switch, a polarizer, or other devices, is placed between the scene or object 10 and the FPA 13 to modulate the photon flux from the aforesaid scene or object 10 for imaging, spectrum, or spectroscopic imaging;
c) or an active modulator, such as a pulsed light source 15, is used to generate modulated image and/or spectroscopic signals;
d) when the modulator is on in one phase (φ1 in the figure), the current generated by the detector 17 is the signal photocurrent Iₛ from object or scene 10, plus the DC background current I_{b} from the radiation 14 not modulated;
e) when the radiation from the imaging target is blocked by the modulator in another phase φ2, only the DC I_{b} is present;
f) by controlling the correlated multicycle integrator synchronically with the modulation control signal, using the same correlated controller 28, the integrator 30 charges the capacitor with the signal and background currents in +1, but discharges it with background current only in φ2;
g) so that the output of 30 is accumulated signal current Iₛ only (plus the shot noise that is not avoidable);
h) so that the aforesaid accumulated signal current Iₛ can be fed to any commercial amplifier and/or display for image, spectrum, or spectral imaging using conventional imaging and/or spectroscopic methods.

8. Lock-in multicycle integration focal plane array (LI-MIFPA), linear or area, which is a special type of multicycle integration focal plane array (MIFPA), linear or area, comprising:
a) all the features of claim 7;
b) with the signal accumulation phase φ1 and background cancellation phase φ2 strictly equal in time.

9. The method of using LI-MIFPA for the detection of extremely weak signals for imaging, spectroscopy, and spectroscopic imaging, which comprises the following steps:
a) all the steps in claim 7;
b) with the signal accumulation phase φ1 and background cancellation phase φ2 strictly equal in time.

10. Gated multicycle integration focal plane array (G-FPA), linear or area, which is a special type of multicycle integration focal plane array (MIFPA), linear or area, comprising:
a) all the features of claim 1;
b) with φ1 lasting an interval of ατ, φ2 lasting an interval of 0 time, and a new phase φ3 lasting an interval of (1−α)τ
c) wherein during phase φ3 the integrator 30 is turned off;
d) wherein α<<1, or (1−α)τ>>τ.

11. The method of using G-MIFPA for the detection of extremely weak signals for imaging, spectroscopy, and spectroscopic imaging, under the condition that the signal duty cycle α is extremely small while the background current is not extremely large, namely α<<1, while Iₛ not <<I_{b}, as in some types of IR fluorescence spectroscopy using nano-second pulse laser excitation, which comprises:
a) all the steps in claim 7;
b) with φ1 lasting an interval of ατ, φ2 lasting an interval of 0 time, and a new phase φ3 lasting an interval of (1−α)τ
c) wherein during phase φ3 the integrator 30 is turned off;
d) wherein α<<1, or (1−α)τ>>τ.

12. Gated lock-in multicycle integration focal plane array (GLI-MIFPA), linear or area, which is a special type of multicycle integration focal plane array (MIFPA), linear or area, comprising:
a) all the features of claim 1;
b) with φ1 lasting an interval of ατ, φ2 lasting an equal interval of ατ, and a new phase φ3 lasting an interval of (1−2α)τ
c) wherein during phase φ3 the integrator 30 is turned off;
d) wherein α<<1, or (1−2α)τ>>τ.

13. The method of using GLI-MIFPA for the detection of extremely weak signals for imaging, spectroscopy, and spectroscopic imaging, under the condition that the signal duty cycle α is extremely small and the background current is extremely large, namely α<<1, and Iₛ<<I_{b}, as in some types of IR fluorescence spectroscopy using nano-second pulse laser excitation, which comprises:
a) all the steps of claim 7;
b) with φ1 lasting an interval of ατ, φ2 lasting an equal interval of ατ, and a new phase φ3 lasting an interval of (1−2α)τ
c) wherein during phase φ3 the integrator 30 is turned off;
d) wherein α<<1, or (1−2α)τ>>τ.

14. The MIFPA structure, circuit design and control timing with shared CMI and sample/hold (one CMI and sample/hold per column), wherein to avoid noises including the reset and capacitor feed-through caused noises during the relatively long time of multicycle integration,
a) a stage of shared row of correlated multicycle integrators (CMI) and sample/hold performs the integration row by row is implemented;
b) wherein with the row shift-register 41 enabling one row of detectors to be connected to the common shared CMI stage 43, assuming row i depicted by 53i, being high, which turns on all the transistors 49ij (j=1, 2, . . . , N for all the cases discussed in this claim) so that the detector 48ij becomes the input of CMI 43j;
c) wherein after row i turns to high, a short pulse of V_{R} will reset the integrator capacitor 24j;
d) wherein by controlling the timing of V₂, V₃ V₄ as shown in FIG. 6, the whole row of CMIs perform multicycle integration at either lock-in, gated, or gated lock-in mode;
e) wherein by the end of integration, the sample/hold switch 51j is turned on to sample the output voltage at node 27j to the hold capacitance of 63j;
f) wherein after the sample, V_{R} resets the capacitance 24j again;
g) wherein at the same time, the modulation signal is shifted a phase of 180 degrees to follow another similar integration, and by the end of the second integration, the row shift register turns off the row i and is ready to turn on the next row i+1;
h) wherein meanwhile, the sample/hold switch 52j is turned on to sample the output voltage at node 27j to the hold capacitance of 64j;
i) wherein at this time, 63j and 64j keep the integrated signals with phase difference of 180 degrees related to the detectors 48ij;
j) wherein after the second sample, the row shift-register enables the next row i+1;
k) wherein at the beginning of the next row integration, the column shift register starts to scan from column 1 to N to the jth column or COLj_to readout the signals of the previous row i;
l) wherein following the enabling of COLj (logical low to turn on PMOS transistor), P transistors 57j and 59j activate the load transistors 55j and 60j, thus transistors 57j and 58j function as source follow, with the pair of voltages at 63j and 64j sensed to the inputs of the differential amplifier 46 at the nodes of 61j and 62j, respectively;
m) wherein these differential signals eliminating the noises, including fixed pattern noises such as from the reset and from the feed-through of the switches, and the differential signals of the whole row i being readout serially at the output 80 before the first sample of the next row i+1 is taken;
n) wherein after the row shift register makes shift from 1 to M, the whole modulated image is addressed.

15. The MIFPA structure, circuit design and control timing with non-shared CMI and shared sample/hold (one CMI per pixel and one sample/hold per column) to avoid noises including the reset and capacitor feed-through caused noises during the relatively long time of multicycle integration,
a) wherein every pixel's input unit includes a CMI preamplifier while a column sample and hold circuitry (sample/hold) is shared to serve the whole area;
b) wherein signals are integrated also row by row, with each row having its specified reset timing in the purpose to save readout time (done during integration);
c) wherein, however, the integration of one row does not forbid the integration of other rows;
d) wherein the row shift register is used to select one row in a time for samples after integration and immediately after it is reset;
e) wherein the differential of the two samples are used to get rid of the reset noise while the differential signals of the row then are readout serially by enabling or scanning the column shift register;
f) wherein the row shift-register 41 enables only one row in a time, and the enabling of the row i makes the connection of the output 27ij (j=1, 2, . . . , N for all the cases discussed in this claim) of the CMIij to the input 54j of the sample/hold circuitry.
g) wherein during the row enabling time, the sample/hold switch 51j is first turned on to sample the output voltage (end of the integration) at node 27ij to the hold capacitance of 63j, then the reset V_{Ri} is enabled to clean all the integration capacitances 24ij at the same row i;
h) wherein after the reset, the sample/hold switch 52j is then immediately turned on to sample the output voltage (at the beginning of the integration) at node 27j to the hold capacitance of 64j;
i) wherein after the second sample, the row shift register 41 turns off the row i, and the input units 45 (i, with j=1, . . . N) start integration again.
j) wherein before the next row is enabled, the signal stored in the shared sample/hold stage is readout by enabling the column shift register 42 which starts to scan COLj to readout the signals of row i;
k) wherein when COLj is enabled (logical low to turn on PMOS transistor), P transistors 57j and 59j active the load transistors 55j and 60j, and thus the pair of voltages at 63j and 64j are sensed to the inputs of the differential amplifier 46 at the nodes of 61j and 62j;
l) wherein the differential output voltages at node 80 are the integration signals from row i;
m) wherein after the readout of row i, the row shift register 41 turns on the next row i+1, and thus, the procedure of sample/hold and readout will be followed again until every pixel in the array is readout to make the image.
